(19) United States
(12) Patent Application Publication
(10) Pub. No.: US 2005/0231220 A1
(43) Pub. Date: Oct. 20, 2005

(54) Terminal of IC test fixture

(76) Inventor: Teng Sheng Hung, Taoyuan (TW)

Correspondence Address: RABIN & DERDO, P.C., Suite 500, 1101 14 Street, N.W., Washington, DC, 20005, US

(21) Appl. No.: 10/823,702

(22) Filed: Apr. 14, 2004

(51) Int. Cl. G01R 31/02

(52) U.S. Cl. 324/754

(57) ABSTRACT

A terminal of IC test fixture comprising a body, a spring contact arm and a soldering portion and there are at least one hollow holes on the body of the terminal. During testing, the electronic charges flow on the terminals generate electromagnetic field at the direction perpendicular to the electrical current flow, and the electronic current flows, which are near, generates electromagnetic fields with different directions, by the compensation and interference of electromagnetic fields each other, making the electromagnetic interference reduced. To suppress the electronic interference, the aforesaid hollow holes subdivide said electronic current flow, and that helps to constrain the electromagnetic interference during testing. Therefore, this invention can minimize electromagnetic interference among terminals for higher efficiency in testing the high frequency transmission IC's.

### BACKGROUND OF THE INVENTION

I. Field of the Invention

This invention relates generally to a terminal of an IC, integrated circuit, test fixture and, more specifically, to a terminal of an IC test fixture having adequate contact force to tested IC pins, low electromagnetic interference, high transmission efficiency and low manufacturing cost, is applied on the test of high frequency transmission IC's.

II. Description of the Prior Art

Heretofore, it is known that the IC testing fixture 7, as shown in FIG. 1, consists of a cover 5, a basement 6 and a plurality of terminals 7. Referring to FIG. 2, the terminal 7 further consists of a spring contact portion 72, a body 71 and a soldering portion 73; the spring contact portion 72 presses a pin of the tested IC downwardly by elastically deformed. The body 71 of the terminal 7 is arranged at the bottom of the spring contact portion 72, holding the terminal 7 into the basement 6 of the IC test fixture, and the soldering portion 73 is stretched downward from the body 71 of the terminal 7, electrically connecting to the PCB, printer circuit board. While the IC is placed onto the basement 6 for testing, the spring contact portion 72 electrically connects with the pin of the tested IC to form an electrical loop.

During the electronic charges flow in the loop, referring to FIG. 2, electromagnetic field is formed along the perpendicular direction of the electronic flow path, especially at the corners of the terminal shape, see the arrow lines in FIG. 2. The outside dimensions of the ICs are smaller in physical size, the pitches of the pins of the ICs are smaller, the frequency of the electrical signal traveling through the terminal 7 is higher, and the electromagnetic field over the terminal 7 is stronger, thus making the electromagnetic interference stronger. Therefore, the electromagnetic interference is more serious to interfere the efficiency of current and signals traveling through the terminals.

### SUMMARY OF THE INVENTION

It is a primary object of the invention to provide a terminal of IC test fixture having low the electromagnetic interference during electrical signals traveling through the terminal.

In order to achieve the objective set forth, the electromagnetic interference caused by the electrical charge flow in a terminal must be reduced, and the Biot Savart law teaches that the strength of the electromagnetic field is proportional to the amount of current flow in the conductor and inverse proportional to the pitch of the electrical charge flowing paths, so it could be understood that the lower electrical current flow and longer distance between electrical charge flowing paths both will reduce the electromagnetic field.

It is not easy to make the pitch larger between the terminals, electrical current flowing paths, because the pitch of the terminals is required smaller and smaller. Thus the only way is to change the current flow path, make it longer, or change the amount of electrical current flow, make it smaller in the terminals, according to the Biot Savart law.

The terminal of an IC test fixture in accordance with the present invention has a plurality hollow holes at the body portion of the terminal, making the electrical current and signals flow to form several paths in the terminal, and each electrical current flows is subdivided from the original electrical current flow.

According to right-hand rule, the straight thumb means the current flow direction and the other four curved fingers mean the electromagnetic field direction which is caused by said current flow. The electromagnetic field caused by the current flow is the coefficient of each electromagnetic fields caused by said subdivided electrical current flows in this invention and the electromagnetic fields will counteract each other. Therefore, the coefficient of the electromagnetic field caused by the electrical current flow travel through the terminals are reduced in this invention and the noises are depressed.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is a cross-sectional view of the prior art;

FIG. 2 is a cross-sectional view of the prior art;

FIG. 3 is a perspective view of the second embodiment the present invention;

FIG. 4 is a perspective view of the first embodiment the present invention;

FIG. 5 is an application view of the second embodiment of the present invention.

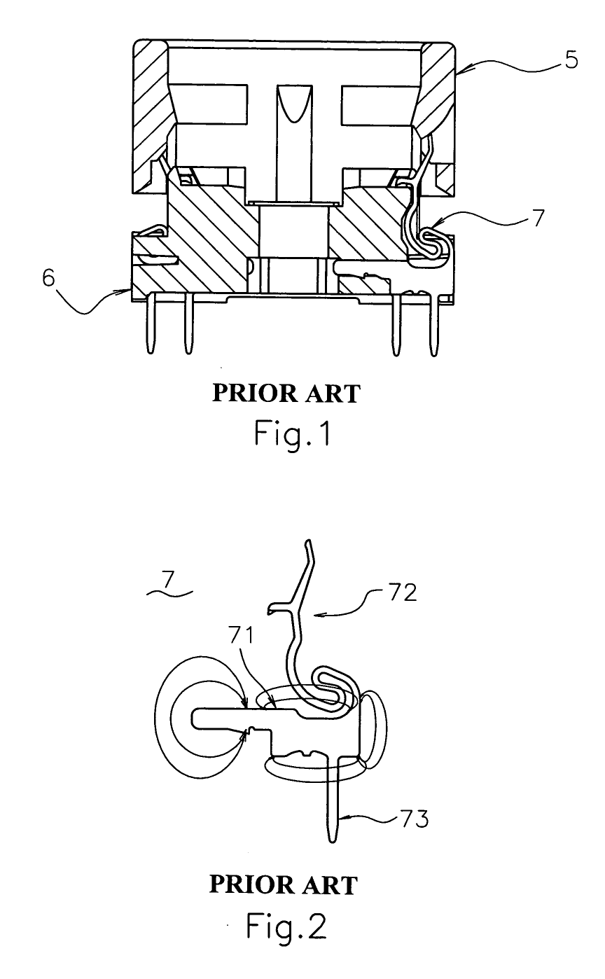

### DESCRIPTION OF THE PREFERRED EMBODIMENT

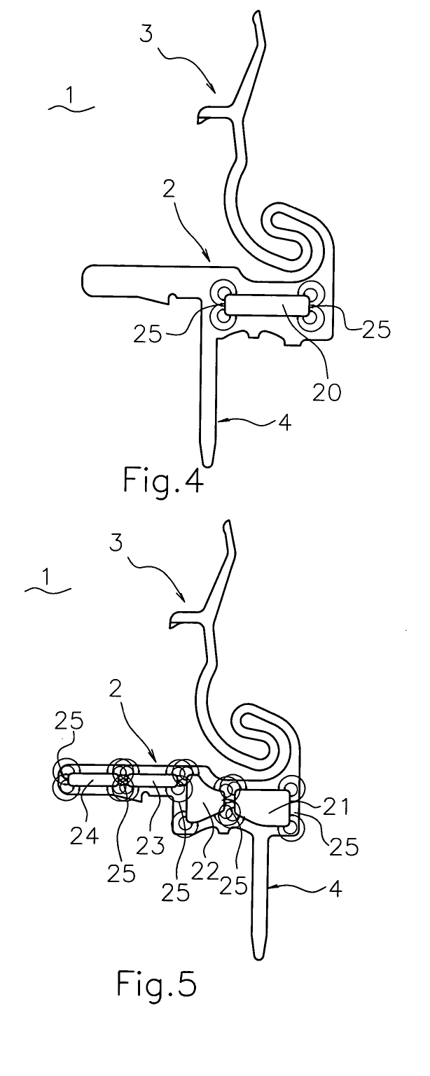

Referring to FIG. 4, the terminal 1 of the present invention, was made of a metal plate, comprises a body 2, a spring contact arm 3 and a soldering portion 4. There is at least one hollow holes 20 at the body 2 of the terminal 1, for forming at least two conductive paths 25 on it, making the electrical current flow subdivided.

An embodiment shown in FIG. 4, after the terminal 1 is installed in the IC test fixture and test an IC, the current flows from spring contact arm 3 to body 2, soldering portion 4 and PCB, or reversed, when current travels through the conductive paths 25 of the body 2 of the terminal 1, electromagnetic fields are generated over the conductive paths 25.

Since the directions of the current flows are the same and the electromagnetic fields of the two adjacent conductive paths 25 are opposite to each other during the current traveling through the body 2 of terminal 1, two electromagnetic fields interfere each other and result the coefficient of the electromagnetic is depressed.

According to the Biot Savart law, the subdivided current is travel around the hollow holes 20 of the body 2 of the terminal 1, and the currents on each conductive path 25 becomes half of the original and the electromagnetic fields will be relatively smaller than a terminal without hollow holes, prior art, and the electromagnetic field over the terminal 2 caused by the electronic currents flow is reduced.

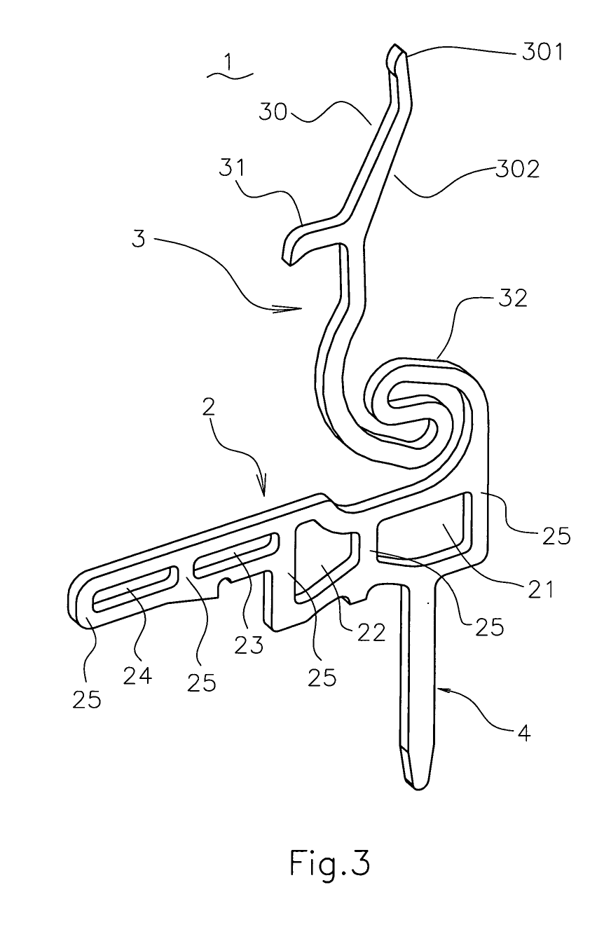

Based on above description, another embodiment of this invention shows in FIG. 3 and FIG. 5, a first hollow hole 21, a second hollow hole 22, a third hollow hole 23 and a fourth hollow hole 24 are hollowed at the body 2 of the terminal, and several electrical conducting paths 25 are formed by the hollow holes 21-24.

The spring contact arm 3 has a protruding tip 30, an arm 31 and an “S” shape hanging arm 32, and the protruding tip 30 further divided into an first actuating portion 301 and a second actuating portion 302, which are stretched from the arm 31, and the arm 31 is stretched from one end of the hanging arm 32, and the other end of the hanging arm 32 is stretched form the body 2 of the terminal, above the first hollow hole 21.

The soldering portion 4 stretches downward from the lower end of the body 2, referring to FIG. 4 and FIG. 5, the soldering portion 4 is stretched from the front side or back side of the lower end of the body 2 of the terminal.

Referring to FIG. 5, when this second embodiment is applied, the electrical current flow is similar as the first embodiment of this invention, aforesaid, subdivided by many conducting paths 25 caused by the hollow holes and the amount of electronic charges in each conducting path 25 is much less than prior art, and the electromagnetic field is much more reduced, so the electromagnetic fields among each adjacent conducting paths 25 are obviously reduced. Base on said, one who is skilled in the art will understand that the more hollow holes on the body 2 of the terminal, the more electromagnetic interference reduced.

While a preferred embodiment of the invention has been shown and described in detail, it will be readily understood and appreciated that numerous omissions, changes and additions may be made without departing from the spirit and scope of the invention.

1. A terminal of IC test fixture comprising:
a body, a spring contact arm and a soldering portion, said spring contact arm stretches up from one end of said body, said soldering portion is on the other end of said connector;
at least one hollow holes are on said body, and a plurality of conducting paths formed.

2. The terminal of IC test fixture recited in claim 1, wherein a hanging arm in “S” shape with elasticity is stretched between the body and the spring contact arm.

3. The terminal of IC test fixture recited in claim 1, wherein said soldering portion is stretched downward from the other end of the body, not the end with said hanging arm, for electrical connecting to PCB.
